(19) United States
(12) Patent Application Publication
(10) Pub. No.: US 2007/0278001 A1
(43) Pub. Date: Dec. 6, 2007

(54) Method and apparatus for a high frequency coaxial through hole via in multilayer printed circuit boards

(76) Inventors: Romi Mayder, San Jose, CA (US); Youhan Younan, Modesto, CA (US)

Correspondence Address: VERIGY, 4700 INNOVATION WAY, BLDG D1, FORT COLLINS, CO, 80528, US

(21) Appl. No.: 11/444,943

(22) Filed: May 31, 2006

(51) Int. Cl. H05K 1/11

(52) U.S. Cl. 174/262

(57) ABSTRACT

A high frequency coaxial through hole via in a multilayer printed circuit board is presented. The high frequency coaxial through hole via may include two traces connected by a plated through hole via and surrounded by more than one ground plane, where the more than one ground planes are capacitively coupled.

### BACKGROUND

In order to connect one layer to another in a conventional multilayer printed circuit board, a through hole via is generally drilled through the entire board thickness. Heretofore, the geometries of the through hole via and surrounding metallization were chosen strictly for manufacturability reasons without regard to the characteristic impedance of the through hole via. As data rates for semiconductor devices continue to increase, characteristic impedance mismatches along the transmission lines of the printed circuit boar affect the signal fidelity, creating unwanted reflections on the signal. These reflections may cause incorrect data to be transmitted along the transmission lines of the printed circuit board.

FIG. 1 represents a graphical illustration of a signal transitioning from layer two 110 to layer six 120 of a multilayer printed circuit board 100. In FIG. 1, the arrows 130 show the metal clearance on layers three 140, four 150 and five 160 of a typical multilayer printed circuit board via hole 170. Typically, with such a multilayer printed circuit board via hole 170, there will be significant reflections of a signal waveform caused by impedance mismatches, especially with high frequency signals.

It would be desirable to have a multilayer printed circuit board assembly that reduces reflections on the signal waveform caused by impedance mismatches of the through hole vias.

### BRIEF DESCRIPTION OF THE DRAWINGS

An understanding of the present teachings can be gained from the following detailed description, taken in conjunction with the accompanying drawings of which:

FIG. 1 illustrates a typical through hole via of a multilayer printed circuit board assembly.

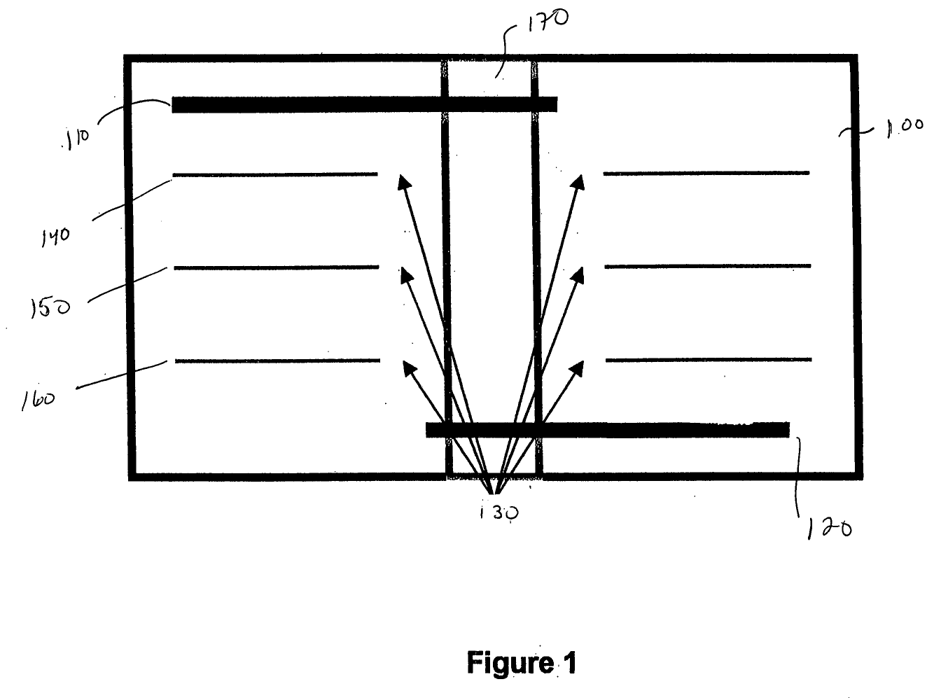

FIG. 2 illustrates a high frequency coaxial via hole in a multilayer printed circuit board assembly in accordance with the present invention.

FIG. 3 shows a flow chart for fabricating a multilayer printed circuit board assembly in accordance with the present invention.

### DETAILED DESCRIPTION

In the present invention, the characteristic impedance of the through hole via is optimized by creating sufficient capacitance between ground layers and adjusting the via drilled hole diameter and clearance to surrounding metallization of the ground planes. This new high frequency through hole via has a via hole characteristic impedance that now matches the characteristic impedance of the traces on the layers which the via will connect together. This will permit a high frequency signal to pass through this entire signal path with minimal reflections on the signal waveform caused by impedance mismatches. The via hole will act essentially as a coaxial transmission line.

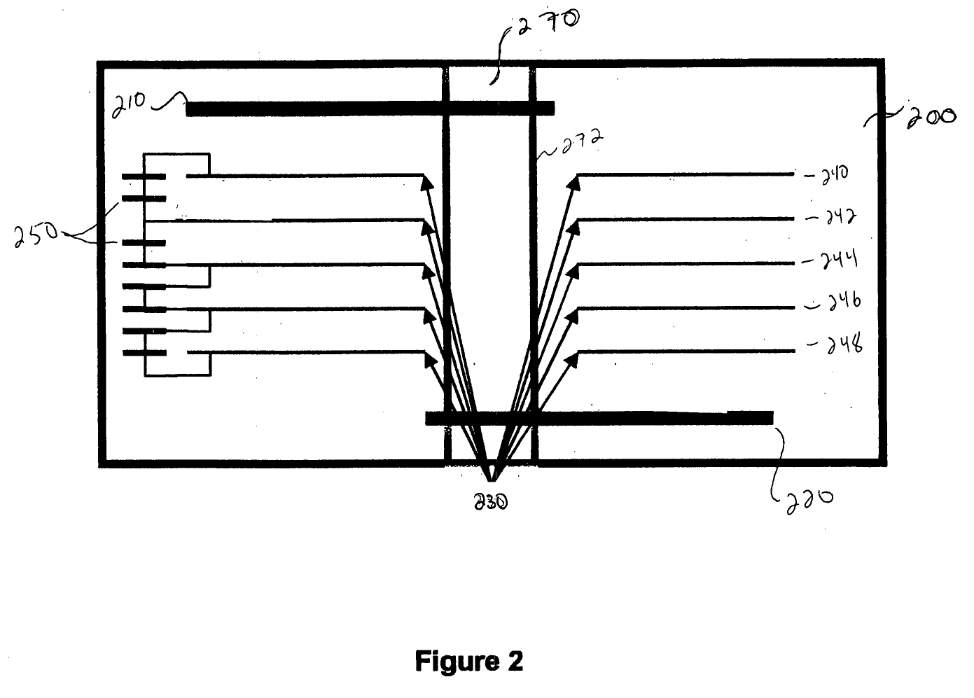

FIG. 2 shows a high frequency coaxial via hole 170 in a multilayer printed circuit board assembly 100 in accordance with the present invention. The multilayer printed circuit board assembly 100 has a trace 110 on layer 2 and a trace 120 on layer 8 with capacitance 250 between all ground layers 3, 4, 5, 6, and 7 (240, 242, 244, 246 and 248). The capacitance on the ground layers creates a ground anti-pad on the ground layers for desired characteristic impedance.

To optimize the characteristic impedance of the through hole via 270, the via hole 270 is treated as a coaxial transmission line. The through hole via 270 may be plated, which acts as a center conductor. The through hole via 270 may be plated with copper as a base material. Additionally, the copper plating may or may not be followed by nickel and then finally gold. The printed circuit board material acts as a dielectric and the metallization in the ground planes 3-7 (240-248) surrounding the plated through hole acts as the shield of the coax transmission line.

By adjusting the separation of the ground planes, sufficient capacitance between the planes can be created to make a high frequency short between the ground planes 3-7 (240-248). Basically, the ground layers 3-7 (240-248) act like a solid copper wall running parallel to the plated 272 through hole 270. Then, the anti-pad 230, or clearance in the ground planes 3-7 (240-248) surrounding the plated through hole 270, will be selected to create the desired characteristic impedance for a given plated through hole diameter.

The anti-pad may be created by selectively etching copper from solid planes of cold rolled or sputtered copper of thickness ranging from 0.1 mil to 0.3 mils.

The characteristic impedance can be adjusted from about 25 ohms up to about 75 ohms for applications where the printed circuit board thickness does not exceed about 0.125 inches. Adjusting the impedance may be adjusted by varying the ratio of the anti-pad to the drilled via hole diameter. As the ratio decreases, the impedance decreases. The ratio increases, the impedance increases.

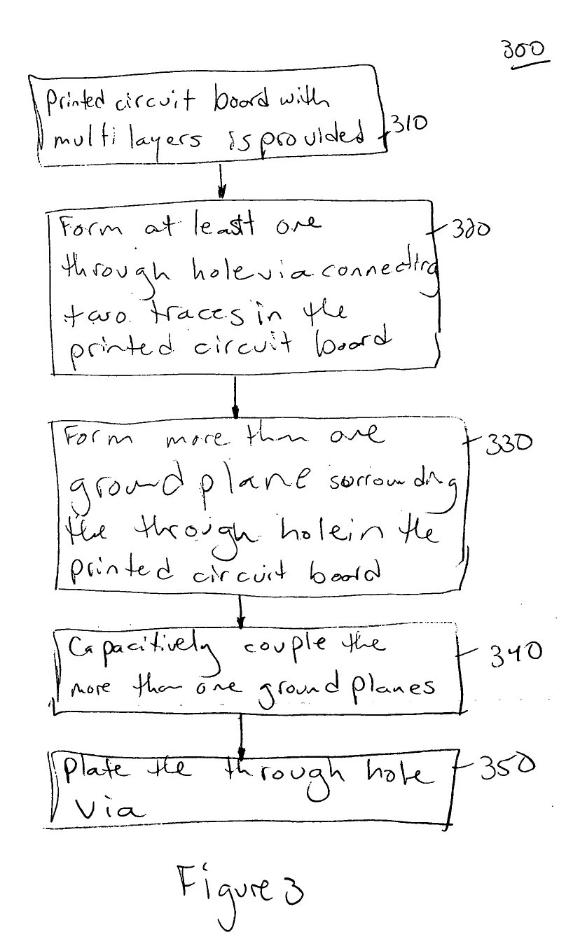

FIG. 3 shows a flow chart 300 for fabricating a multilayer printed circuit board assembly 200 in accordance with the present invention. A printed circuit board 200 is provided 310. At least one through hole via 270 connecting two traces 210 and 220 in the printed circuit board 200 is formed 320. More than one ground plane 240-248 surrounding the through hole via 270 in the printed circuit board 200 is formed 330. The more than one ground planes 240-248 are capacitively coupled 340. The through hold via 270 is plated 350. The plating may be copper, copper/nickel/gold or other known via plating material.

It will be readily apparent that the above fabrication method may be accomplished in different orders than that given. Also, many different materials may be used without deviating from the heart of the invention.

1. A high frequency coaxial through hole via in a multilayer printed circuit board assembly comprising:
a printed circuit board;
a first trace in the printed circuit board;
a second trace in the printed circuit board;
a plated through hole via connecting the first trace and the second trace in the printed circuit board; and
more than one ground plane surrounding the plated through hole via and between the first and second traces in the printed circuit board, wherein the more than one ground planes are capacitively coupled.

2. The high frequency coaxial through hole via in a multilayer printed circuit board assembly in accordance with claim 1, wherein the via hole acts like a coax transmission line.

3. The high frequency coaxial through hole via in a multilayer printed circuit board assembly in accordance with claim 1, wherein the plated through hole via acts like a center conductor.

4. The high frequency coaxial through hole via in a multilayer printed circuit board assembly in accordance with claim 1, wherein the metallization in the ground planes surrounding the plated through hole act as a shield.

5. The high frequency coaxial through hole via in a multilayer printed circuit board assembly in accordance with claim 1, further comprising an anti-pad of a predetermined characteristic impedance.

6. A method for fabricating a high frequency coaxial through hole via in a multilayer printed circuit assembly comprising:
providing a multilayer printed circuit board;
forming at least one through hole via connecting two traces in the printed circuit board;
forming more than one ground place surrounding the through hole via in the printed circuit board;
capacitively coupling the more than one ground planes and
plating the through hole via.

7. The method for fabricating a high frequency coaxial through hole via in a multilayer printed circuit assembly in accordance with claim 6, further comprising:
forming an anti-pad of a predetermined characteristic impedance.
